(19) United States
(12) Patent Application Publication
(10) Pub. No.: US 2016/0109479 A1
(43) Pub. Date: Apr. 21, 2016

(54) Continuous Breadboard

(71) Applicant: Bassem Alhalabi, Boca Raton, FL (US)

(72) Inventor: Bassem Alhalabi, Boca Raton, FL (US)

(21) Appl. No.: 14/517,817

(22) Filed: Oct. 18, 2014

(51) Int. Cl. G01R 1/04

(52) U.S. Cl. CPC G01R 1/0416

(57) ABSTRACT

A continuous breadboard provides a continuous surface having no gaps or barriers. The continuous surface enables electrical components to position anywhere on the surface of the breadboard. The electrical components orient along any row or column on the surface of the breadboard. The capacity to position anywhere on the breadboard enables variously sized and dimensioned electrical components and their lead ends to integrate with the breadboard in myriad configurations. Additionally, multiple electrical components may be staked side-by-side for lateral electrical connectivity. The breadboard comprises a plate that forms a continuous surface with no gaps or barriers. The plate comprises banks disposed to abut an adjacent bank, such that no gaps are formed between banks. Apertures that extend twelve columns and one row across the banks provide electrical connections. The banks are grouped into a sets that share a common electrical continuity and can include an alternating AABBAABBCCDD arrangement.

### FIELD OF THE INVENTION

The present invention relates generally to a continuous breadboard for building and testing circuits. More so, a continuous breadboard is comprised of sets of banks with shared electrical connectivity that are configured to integrate with electrical components and provide a continuous surface with no gaps or barriers for enhancing the building and testing of electrical circuits.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon.

By way of educational background, another aspect of the prior art generally useful to be aware of is that electrical circuits are typically prototyped using a printed circuit board which is commonly referred to as a breadboard. A typical breadboard contains a plurality of plated through holes that are coupled to conductive pins. Discrete electrical components are soldered or simply inserted into the plated holes and coupled together by wires which are wrapped around corresponding pins. The discrete components may include integrated circuits, individual transistors, resistors, capacitors, diodes that are all connected to create an electrical circuit.

Typically, a solder-less breadboard is a reusable platform on which temporary electronic circuits can be built, tested, modified and evaluated without having to solder the various electronic components and wires in place. It comprises an insulated electrical socket, or sockets that contain spring clip electrical connectors with a plurality of contacts spaced on 0.1″ centers that individual pins or leads of electronic components and wires plug into.

There are two basic parts to the breadboard. The first is a distribution strip, which contains one or two rows of connectors running in the same direction as the row that are all electrically connected together, such that it distributes an electrical signal or power to every contact in the row from end to end, with each row electrically isolated from each other, thus distributing two separate voltages or signals. The second is a terminal strip, which typically contains two rows of connectors each having five contacts on 0.1 inch centers running perpendicular to the direction of the row. All the connectors are parallel to each other and electrically isolated from each other.

In many instances, the two rows are electrically isolated from each other and the nearest contacts in each row are spaced on 0.3 inch centers, such that integrated circuits in DIP packages can be plugged into the center of the terminal strip, with each pin plugging into a separate connector. This leaves four available contacts running perpendicular to the integrated circuit and parallel to each other to carry signals to or from the pins. A terminal strip is placed between two distribution strips, such that power or signals run parallel to each other on opposite sides of the terminal strip and perpendicular to the signals on the terminal strip, such that power can be applied to any desired connector on the terminal strip by a short piece of wire from the closest contact on the distribution strip.

Often, connecting together individual electrical components for building or testing the circuit is a time consuming process, requiring the user to wire wrap and/or solder each lead of each component. Additionally, the circuit(s) must be tested and reworked/modified if any errors or undesirable outputs are detected. Many circuits are constructed from a number of basic circuits, which each have to be individually tested.

In many instances, the breadboard comprises an upper electrical bank and a lower electrical bank separated by a gap. The gap between the upper electrical bank and the lower electrical bank is often spaced at 0.2″ wide, which is greater than the 0.1″ width of many electrical components, such as a chip. The gap can be problematic in that it restricts the chip from positioning in the region proximal to the gap, or the chip may be required to be 0.2″ or wider. These limitations reduce the possible configurations of the electrical component for building and testing the circuit. It can also be difficult to stake multiple chips in a side by side configuration due to the gap.

Even though the above cited systems and methods for breadboards address some of the needs of the market, a continuous breadboard comprised of sets of banks with shared electrical connectivity that provides a continuous surface with no gaps or barriers is still desired. Breadboards that integrate with electrical components have been used for building and testing prototype circuits in the past, yet none with the present characteristics of the present invention. See U.S. Pat. No. 8,658,909; U.S. Pat. No. 5,339,219; U.S. Pat. No. 7,273,377 and U.S. Pat. No. 5,856,636.

### SUMMARY OF THE INVENTION

The present invention is directed to a continuous breadboard comprised of sets of banks with shared electrical connectivity that are configured to integrate with electrical components and provide a continuous surface with no gaps or barriers for enhancing the building and testing of electrical circuits. The continuous breadboard provides a continuous surface with no gaps for increasing flexibility during the building and testing of electrical circuits. The continuous surface enables variously sized and dimensioned electrical components to position anywhere on the surface of the continuous breadboard. The electrical components may orient along any row or column on the surface of the continuous breadboard. The capacity to position anywhere on the continuous breadboard enables variously sized and dimensioned electrical components and their lead ends to integrate with the continuous breadboard in myriad combinations and configurations. Additionally, multiple electrical components may be staked side-by-side for lateral electrical connectivity. This creates greater flexibility when building and testing circuits.

The breadboard comprises a plate that forms a continuous surface with no gaps or other restrictive barriers. The plate comprises a plurality of banks, such as electrical panel banks. Each bank is disposed to abut an adjacent bank, such that no gaps are formed between banks. Each bank is configured to carry at least two columns and at least one row of apertures. The apertures provide electrical connectivity points that may be efficacious for receiving a plurality of electrical components and their corresponding lead ends, and enabling electrical conductivity through a plurality of conductive strips aligned along the columns of each bank.

In some embodiments, the banks may be grouped into a set of banks. Each set of banks shares a common electrical connectivity. In one embodiment, the sets of banks include two A banks, two B banks, one C bank, and one D bank. The sets are arranged such that each set of banks that forms a common electrical connectivity is disposed in an alternating arrangement with the other banks. For example, an AABBAABBCCDD configuration of banks allows the A banks to alternate their position on the plate with the B banks, and avoid contact with the C and D banks completely. In this configuration two A banks abut each other, and two B banks abut each other in an alternating arrangement. In another example, the sets of banks may be configured in an AABBAABBAABB, or an ABCDABCDABCD layout. In any case, the banks may be reconfigured into various combinations, depending on the desired circuit construction and testing requirements.

Once the desired bank configuration has been assembled, the plurality of electrical component leads may then mate with the appropriate apertures in the columns and rows to connect the banks and sets of banks together. For example, a chip having a 4×7 pin layout couples with a set of banks forming a bridge between an AA and a BB set of banks. The absence of a gap allows the chip to be integrated anywhere along the columns and rows of the banks. In this manner, greater flexibility of electrical component sizes, dimensions, and positioning is allowed for building and testing the circuit.

In one aspect, a continuous breadboard for building and testing a circuit comprises:
a plate configured to provide mechanical support and electrical continuity,
the plate comprising a plurality of banks, each bank comprising at least two columns and
at least one row of spaced apart apertures, each aperture defining an electrical contact point,
each bank disposed to abut an adjacent bank,
wherein the adjacent banks are arranged to enable the electrical continuity,
at least two of the banks grouped into a set of banks configured to share a common electrical continuity, each set of banks disposed to form an alternating arrangement with the other sets of banks; and
a plurality of conductive strips disposed to align with the at least two columns of spaced apart apertures in each bank, each conductive strip arranged to be parallel and electrically isolated from the other conductive strips.

In another aspect, the continuous breadboard comprises a solder-less breadboard.

In another aspect, the plate comprises a top surface and bottom surface.

In another aspect, each bank comprises twelve columns and one row of spaced apart apertures.

In another aspect, the spaced apart apertures are defined by a space between each aperture, the space comprising 0.1 inches.

In another aspect, the spaced apart apertures comprise insulated sockets.

In another aspect, the plurality of banks abut against each other to form a continuous surface.

In another aspect, the plurality of banks comprises an electrical panel bank.

In another aspect, the set of banks comprise four sets of banks.

In another aspect, the four sets of banks comprise a set of four A banks sharing a common electrical connectivity, a set of four B banks sharing a common electrical connectivity, a set of two C banks sharing a common electrical connectivity, and a set of two D banks sharing a common electrical connectivity.

In another aspect, the four sets of banks are configured in an AABBAABBCCDD alternating configuration.

In another aspect, the four sets of banks are configured in an AABBAABBAABB alternating configuration, or an ABCDABCDABCD alternating configuration.

In another aspect, the plurality of conductive strips comprise spring clip electrical connectors and wires.

In another aspect, the plurality of conductive strips are disposed on the bottom surface of the plate for conducting an electrical current between a plurality of electrical component lead ends.

In another aspect, the plurality of electrical component lead ends extend from at least one electrical component.

In another aspect, the at least one electrical component comprises a chip having a 4×7 pin layout and/or a connector having a 2×4 pin layout.

In another aspect, the plate comprises a peripheral joinder configured to enable attachment with at least one additional plate.

In another aspect, the peripheral joinder comprises a slot and a protrusion configured to couple together.

In a second aspect, a continuous breadboard for building and testing a circuit comprises:
a plate configured to provide mechanical support and electrical continuity for a plurality of electrical component lead ends, the plate comprising a top surface and a bottom surface,
the plate further comprising a plurality of banks, each bank comprising one column and twelve rows of spaced apart apertures, each aperture defining an electrical contact point, each aperture configured to enable passage of the plurality of electrical component lead ends,
each bank disposed to abut an adjacent bank,
wherein the plurality of electrical component lead ends connect the adjacent banks to form a continuous electrical circuit between the adjacent banks,
at least two of the banks grouped into four sets of banks configured to share a common electrical continuity, the four sets of banks comprising at least a set of four A banks, a set of four B banks, a set of two C banks, and a set of two D banks,
the four sets of banks disposed to form an alternating arrangement with each other,
wherein the plurality of electrical component lead ends connect any of the four sets of banks; and
a plurality of conductive strips disposed to align with the at least two columns of spaced apart apertures in each bank, the plurality of conductive strips arranged on the bottom surface of the plate, each conductive strip arranged to be parallel and electrically isolated from an adjacent conductive strip on an adjacent column, the plurality of conductive strips comprising spring clip electrical connectors.

In yet another aspect, the four sets of banks are configured in an AABBAABBCCDD alternating configuration.

One objective of the present invention is to integrate the continuous breadboard with a plurality of electrical component lead ends for building, testing, modifying, and evaluating an electronic circuit.

Another objective is to provide an aid for properly laying out circuit components in a way that minimizes errors and enables students to visualize the tangible circuit that corresponds with a schematic circuit diagram.

Another objective is to provide a breadboard with a continuous surface having no gaps or barriers that allows variously sized electrical components and their lead ends to build and test electrical circuits.

Another objective is to integrate a plurality of electrical components and their lead ends anywhere on the breadboard and in any columns and rows of the banks.

Another objective is to enable multiple electrical components to be staked side-by-side for lateral electrical connectivity.

Another objective is to arrange four sets of banks, each bank having a similar electrical conductivity, into alternating arrangements.

Yet another objective is to form an AABBAABBCCDD alternating configuration with a set of four A banks, a set of four B banks, a set of two C banks, and a set of two D banks.

Yet another objective is to connect the different sets of banks with a chip having a 4×7 pin layout and/or a connector having a 2×4 pin layout.

Yet another objective is to color code the sets of banks for easy identification and integration with the appropriate electrical component.

Yet another objective is to couple the electrical component lead ends with the appropriate spaced apart aperture to build and test a circuit.

Yet another objective is to extend the conductive strips along each column in the banks to form multiple columns of electrical conductivity for each bank.

These and other advantages of the invention will be further understood and appreciated by those skilled in the art by reference to the following written specification, claims and appended drawings.

### BRIEF DESCRIPTION OF THE DRAWINGS

The invention will now be described, by way of example, with reference to the accompanying drawings, in which:

FIG. 1 illustrates a top view of an exemplary schematic diagram showing a traditional breadboard having an upper bank and a lower bank separated by a gap, in accordance with an embodiment of the present invention;

FIG. 2 illustrates a top view of an exemplary schematic diagram showing an exemplary continuous breadboard having four sets of banks in an alternating configuration, in accordance with an embodiment of the present invention; and

FIG. 3 illustrates a top view of an exemplary schematic diagram showing an exemplary circuit connection for an exemplary set of A banks, an exemplary set of B banks, an exemplary set of C banks, and an exemplary set of D banks, in accordance with an embodiment of the present invention.

Like reference numerals refer to like parts throughout the various views of the drawings.

### DETAILED DESCRIPTION OF THE INVENTION

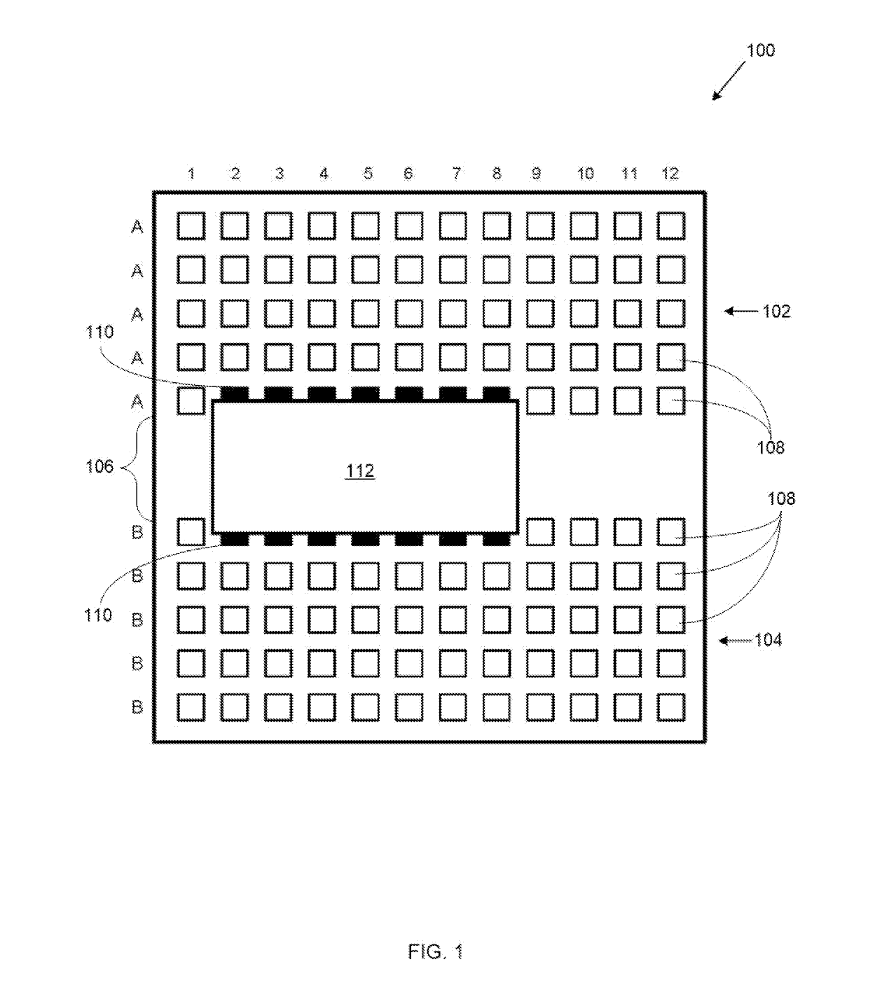

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

At the outset, it should be clearly understood that like reference numerals are intended to identify the same structural elements, portions, or surfaces consistently throughout the several drawing figures, as may be further described or explained by the entire written specification of which this detailed description is an integral part. The drawings are intended to be read together with the specification and are to be construed as a portion of the entire “written description” of this invention as required by 35 U.S.C. §112.

In one embodiment of the present invention presented in FIGS. 1-3, a continuous breadboard 200 is comprised of a plurality of banks 210 that are configured to integrate with at least one electrical component 112 and provide a continuous surface with no gap 106 or other restrictive barrier. The absence of a gap 106 removes space limitations, and thus serves to enhance the flexibility for possible configurations and the electrical components 112 used to build and test electrical circuits.

In some embodiments, a continuous surface with no gap 106 on the continuous breadboard 200 enables the at least one electrical component 112 to orient along any row or column on the continuous breadboard 200. The capacity to position the electrical component 112 anywhere on the continuous breadboard 200, without the restriction imposed by the gap 106 enables variously sized and dimensioned electrical components 112 and a plurality of electrical component lead ends 110 to integrate with the continuous breadboard 200 in numerous combinations and configurations. Additionally, the absence of the gap 106 allows for multiple electrical components 112 to be staked side-by-side for lateral electrical connectivity since the space limitations imposed by the gap 106 are removed. This creates greater flexibility when building and testing electrical circuits.

As referenced in FIG. 1, a traditional solder-less breadboard 100 provides a reusable platform on which temporary electronic circuits can be built, tested, modified, and evaluated without having to solder the various electronic components and wires in place. The traditional solder-less breadboard 100 comprises an insulated electrical sockets 108 that contain spring clip electrical connectors with a plurality of contacts spaced on 0.1″ centers. In this manner, individual pins or leads from the electronic component and wires can directly plug into the appropriate socket 108 for building and testing circuits.

The traditional solder-less breadboard 100 comprises an upper electrical bank 102 and a lower electrical bank 104 separated by a gap 106. Those skilled in the art, in light of the present teachings, will recognize that the gap 106 between the upper electrical bank 102 and the lower electrical bank 104 is often spaced at 0.2″ wide, which is greater than the 0.1″ width of many electrical component 112, such as a chip. The gap 106 may restrict the electrical component 112 from positioning in the region proximal to the gap 106, unless the electrical component 112 is 0.2″ or wider. These limitations reduce the possible configurations of the electrical component 112 for building and testing the circuit.

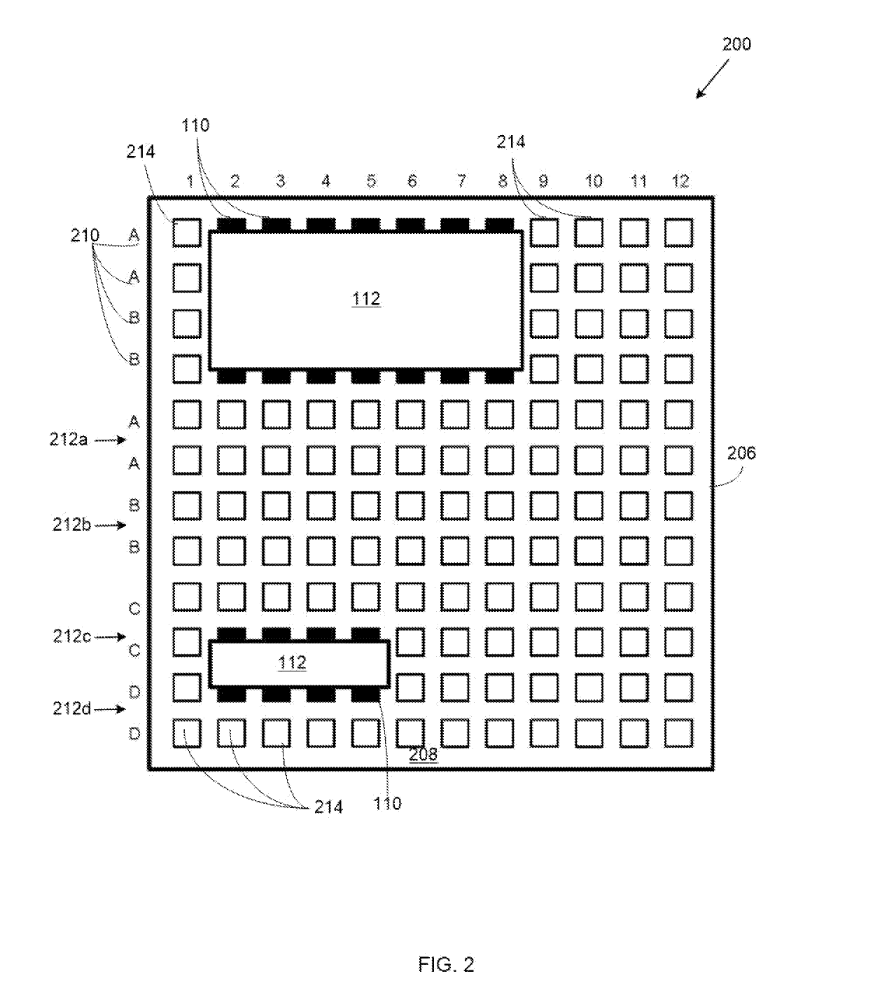

Turning now to FIG. 2, the continuous breadboard 200 provides many of the same functions of the traditional solder-less breadboard 100, except that the gap 106 is not present. This enables the utilization of myriad sizes, dimensions, and orientations of electrical components 112 and electrical component lead ends 110. In one embodiment, the continuous breadboard 200 comprises a perforated block of plastic with numerous tin plated phosphor bronze or nickel silver alloy spring clips under the perforations. However, any number of material compositions and sizes for the continuous breadboard 200 may be used.

In some embodiments, the continuous breadboard 200 may include a plate 206 that forms a continuous surface with no gap 106. The plate 206 comprises a top surface 208 and a bottom surface (not shown). The top surface 208 may include schematic images for guiding attachment with the at least one electrical component 112. The bottom surface provides the conductivity components used to conduct electricity throughout. In some embodiments, a power box (not shown) may be utilized to power the continuous breadboard 200. The bottom surface may form a supportive base for holding the power box. The power box may include a rechargeable battery to provide power. The rechargeable battery may be charged with an exterior power cord, such as a USB cable. The power box can provide various voltages, including, without limitation, 3, 3.3, 3.7, 5, 6, 9, and 12 volts. In another embodiment, a power strip (not shown) extends along an upper, lower, or lateral edge of the bottom surface of the plate 206.

In some embodiments, the plate 206 may be integrated into the continuous breadboard 200, or may detachably join therewith. In one alternative embodiment, the plate 206 comprises a peripheral joinder (not shown) configured to enable attachment with at least one additional plate. In this manner, multiple plates 206 can be cascaded to build a large breadboard. In one embodiment, the peripheral joinder may include grooves and notches on opposite sides configured to fasten at least two plates 206 together. However, in other embodiments, the peripheral joinder may include, without limitation, magnets, adhesives, screws, bolts, and frictional fasteners.

The plate 206 comprises a plurality of banks 210, such as electrical panel banks. The plurality of banks 210 may be integrated into the plate 206, or detachably join therewith. Each bank 210 is disposed to abut an adjacent bank 210, such that no gaps are formed between banks 210. In some embodiments, each bank 210 may be configured to carry at least two columns and at least one row of spaced apart apertures 214. The spaced apart apertures 214 are defined by a space between each aperture of 0.1″. The 0.1″ space dictates the number of electrical components 112 that can mate with the apertures 214 in each bank 210. In one embodiment, each bank comprises twelve columns and one row of spaced apart apertures 214. In this configuration, an electrical component 112 having a width of 0.3″ could attach across three rows of apertures 214.

Those skilled in the art will recognize that the present invention enables integrating a plurality of electrical components 112 and their lead ends 110 anywhere on the banks 210 and in any columns and rows on the banks 210. This flexible configuration allows for the use of eclectic types of electrical components 112. In some embodiments, the electrical component 112 may include a chip having a width of 0.1″, 0.3″, or 0.5″. Additional possible electrical components 112 may include, without limitation, a connector, a resister, a capacitor, an inductor, a diode, a transistor, a light emitting diode, a ROM module, and a pin. The plurality of electrical component lead ends 110 may include, without limitation, wires and hook-up wire ends.

The spaced apart apertures 214 may be efficacious for receiving at least one electrical component 112 and the corresponding lead ends 110, and enabling electrical conductivity through a plurality of conductive strips (not shown) aligned along the columns of each bank 210. In one embodiment, the apertures 214 may include twelve apertures 214 extending across a row with a 0.1″ space between reach apertures 214. However, in other embodiments, ten, twenty, forty apertures 214 may extend across rows or columns of the banks 210, depending on the circuitry needs and size of the circuit being built or tested. However, additional numbers of apertures 214 may be used.

In one embodiment, the spaced apart apertures 214 comprise insulated sockets that operatively connect with wiring and spring clip electrical connectors on the conductive strips. The electrical conductivity between the electrical component lead ends 110 and the conductive strip at each aperture 214 is then allowed to flow in the desired column. In operation, electrical component lead ends 110 engage the spring clip electrical connectors on the conductive strips. The electrical current flows down the column for each bank. Generally, each conductive strip is arranged to be parallel and electrically isolated from the other conductive strips.

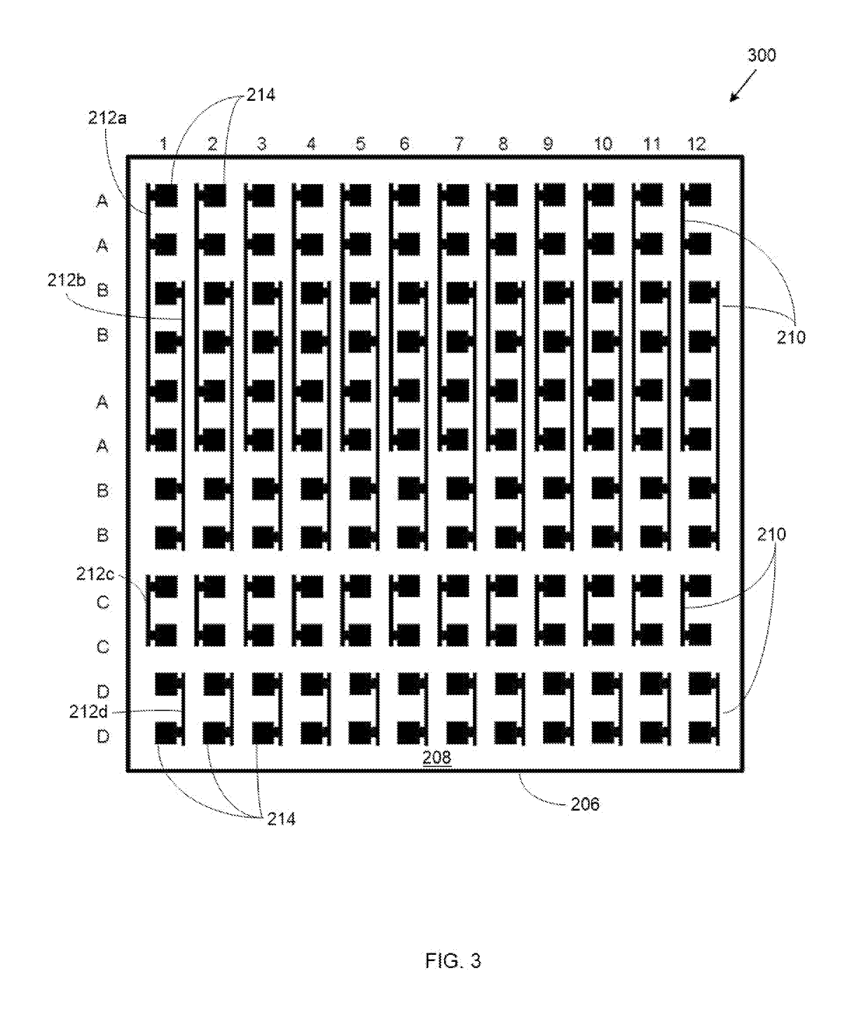

As referenced in FIG. 3, a breadboard circuitry 300 shows the electrical connectivity for the sets of panels 212a, 212b, 212c, 212d. In the breadboard circuitry 300, the banks 210 may be grouped into a set of banks 212a, 212b, 212c, 212d. Each set of banks 212a, 212b, 212c, 212d shares a common electrical connectivity along a respective column in the plate 206. In one embodiment, the set of banks 212a, 212b, 212c, 212d include: a set of four A banks sharing a common electrical connectivity; a set of four B banks sharing a common electrical connectivity; a set of two C banks sharing a common electrical connectivity; and a set of two D banks sharing a common electrical connectivity. The set of banks 212a, 212b, 212c, 212d are arranged such that each set of banks 212a that forms a common electrical connectivity is disposed in an alternating arrangement with the other sets of banks 212b, 212c, 212d. For example, four apertures 214 in the A1 column form a circuit through a circuit bus, four apertures 214 in the B1 column form a circuit through a circuit bus, two apertures 214 in the C1 column form a circuit through a circuit bus, and two apertures 214 in the D1 column form a circuit through a circuit bus. The banks 210 never form a circuit with each other. Though the alternating position of each bank 210 relative to the other banks 210 is determinative of the placement for the electrical component 112.

In one embodiment, an AABBAABBCCDD configuration (FIGS. 2 and 3) allows the two A banks to alternate their position with the two B banks, and avoid adjacent positioning with the C and D banks completely. In this configuration two A banks abut two B banks; the two B banks abut a second of two A banks; the second of two A banks abut a second of two B banks; the second two B banks abut two C banks; and the two C banks abut two D banks, all in an alternating arrangement. However, in alternative embodiments, it is possible that only one A bank is used, forming an ABBBCCDDCCDD configuration. In another example, the set of banks 212a, 212b, 212c, 212d may be configured in an AABBAABBAABB configuration, or an ABCDABCDABCD configuration, or an ABABABABABAB configuration, or an ABCABCABCABC configuration. In any case, the banks 210 may be reconfigured into various combinations, depending on the desired circuit construction and testing requirements. The capacity to create myriad combinations from the set of banks 212a, 212b, 212c, 212d provides great flexibility for the types and orientations of electrical components 112 that can be used with the continuous breadboard 200.

From the desired bank configuration, the electrical component leads 110 can mate with the appropriate apertures 214 in the columns and rows to connect the sets of banks 212a, 212b, 212c, 212d together. The electrical conductivity between the electrical component lead ends 110 and the conductive strip at each aperture 214 is then allowed to flow through the column between the different set of banks 212a, 212b, 212c, 212d. For example, a chip having a 4×7 pin layout couples with a set of banks 212a, 212b to form a circuitry bridge between an AA and a BB set of banks. In another example, a connector having a 2×4 pin layout connects a CC and a DD set of banks 212c, 212d. In an alternative embodiment, each set of banks 212a, 212b, 212c, 212d is color coded to provide fast and accurate identification while connecting the electrical component leads 110 with the appropriate apertures 214. For example, the A set of banks 212a are red, the B set of banks 212b are blue, the C set of banks 212c are blue, and the D set of banks 212d are yellow.

In either case, the absence of a gap 106 enables the electrical component 112 to position onto any column or row on the banks 210, and connect any set of banks 212a, 212b, 212c, 212d. Additionally, multiple electrical components 112 may be staked side-by-side for lateral connectivity. In this manner, myriad combinations of electrical circuits may be built and tested while minimizing errors and enabling the visualization of the tangible circuit that corresponds with a schematic circuit diagram.

Since many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What I claim is:

1. A continuous breadboard for building and testing a circuit, the breadboard comprises:
a plate configured to provide mechanical support and electrical continuity,
the plate comprising a plurality of banks, each bank comprising at least two columns and at least one row of spaced apart apertures, each aperture defining an electrical contact point,
each bank disposed to abut an adjacent bank,
wherein the adjacent banks are arranged to enable the electrical continuity,
at least two of the banks grouped into a set of banks configured to share a common electrical continuity, each set of banks disposed to form an alternating arrangement with the other sets of banks; and
a plurality of conductive strips disposed to align with the at least two columns of spaced apart apertures in each bank, each conductive strip arranged to be parallel and electrically isolated from the other conductive strips.

2. The breadboard of claim 1, wherein the continuous breadboard comprises a solder-less breadboard.

3. The breadboard of claim 1, wherein the plate comprises a top surface and bottom surface.

4. The breadboard of claim 1, wherein each bank comprises twelve columns and one row of spaced apart apertures.

5. The breadboard of claim 1, wherein the spaced apart apertures are defined by a space between each aperture, the space comprising 0.1 inches.

6. The breadboard of claim 1, wherein the spaced apart apertures comprise insulated sockets.

7. The breadboard of claim 1, wherein the plurality of banks comprises a color coded electrical bank.

8. The breadboard of claim 1, wherein the plurality of banks abut against each other to form a continuous surface.

9. The breadboard of claim 1, wherein the set of banks comprise four sets of banks.

10. The breadboard of claim 9, wherein the four sets of banks comprise a set of four A banks sharing a common electrical connectivity, a set of four B banks sharing a common electrical connectivity, a set of two C banks sharing a common electrical connectivity, and a set of two D banks sharing a common electrical connectivity.

11. The breadboard of claim 10, wherein the four sets of banks are configured in an AABBAABBCCDD configuration.

12. The breadboard of claim 11, wherein the four sets of banks are configured in an AABBAABBAABB configuration, or an ABCDABCDABCD configuration, or an ABABABABABAB configuration, or an ABCABCABCABC configuration.

13. The breadboard of claim 1, wherein the plurality of conductive strips comprise spring clip electrical connectors and wires.

14. The breadboard of claim 1, wherein the plurality of conductive strips are disposed on the bottom surface of the plate for conducting an electrical current between a plurality of electrical component lead ends.

15. The breadboard of claim 1, wherein the plate comprises a peripheral joinder configured to enable attachment with at least one additional plate.

16. A continuous breadboard for building and testing a circuit, the breadboard comprises:
a plate configured to provide mechanical support and electrical continuity for a plurality of electrical component lead ends, the plate comprising a top surface and a bottom surface,
the plate further comprising a plurality of banks, each bank comprising one column and twelve rows of spaced apart apertures, each aperture defining an electrical contact point, each aperture configured to enable passage of the plurality of electrical component lead ends,
each bank disposed to abut an adjacent bank,
wherein the plurality of electrical component lead ends connect the adjacent banks to form a continuous electrical circuit between the adjacent banks,
at least two of the banks grouped into four sets of banks configured to share a common electrical continuity, the four sets of banks comprising at least a set of four A banks, a set of four B banks, a set of two C banks, and a set of two D banks,
the four sets of banks disposed to form an alternating arrangement with each other,
wherein the plurality of electrical component lead ends connect any of the four sets of banks;
a plurality of conductive strips disposed to align with the at least two columns of spaced apart apertures in each bank, the plurality of conductive strips arranged on the bottom surface of the plate, each conductive strip arranged to be parallel and electrically isolated from an adjacent conductive strip on an adjacent column, the plurality of conductive strips comprising spring clip electrical connectors; and
at least one power strip configured to provide power to the breadboard, the at least one power strip disposed to align along an edge of the bottom surface.

17. The breadboard of claim 16, wherein the four sets of banks are configured in an AABBAABBCCDD alternating configuration.

18. The breadboard of claim 16, wherein the plurality of banks abut against each other to form a continuous surface.
